(19) United States
(12) Patent Application Publication
(10) Pub. No.: US 2008/0290889 A1
(43) Pub. Date: Nov. 27, 2008

(54) Method of destructive testing the dielectric layer of a semiconductor wafer or sample

(75) Inventor: Robert J. Hillard, Avalon, PA (US)

Correspondence Address: THE WEBB LAW FIRM, P.C., 700 KOPPERS BUILDING, 436 SEVENTH AVENUE, PITTSBURGH, PA, 15219, US

(73) Assignee: Solid State Measurements, Inc., Pittsburgh, PA (US)

(21) Appl. No.: 11/805,788

(22) Filed: May 24, 2007

(51) Int. Cl. G01R 31/26

(52) U.S. Cl. 324/765

(57) ABSTRACT

In a method of testing a semiconductor wafer or sample having a dielectric layer overlaying a substrate of semiconducting material, a contact is caused to touch a top surface of the dielectric layer. At least a portion of the contact touching the dielectric layer is formed of iridium. A controlled electrical stimulus that causes the dielectric layer to breakdown and an electrically conductive path to form through the dielectric layer is applied to the contact touching the top surface of the dielectric layer. Either a value of the controlled electrical stimulus where breakdown of the dielectric layer occurs or a time for the breakdown of the dielectric layer to occur in response to the application of the controlled electrical stimulus is determined. From the thus determined value or time, a determination can be made whether the dielectric layer is within acceptable tolerance.

### BACKGROUND OF THE INVENTION

1. Field of the Invention

The present invention relates to testing of semiconductor wafers or samples and, more particularly, to destructive testing of ultra-thin dielectric layers overlaying substrates of semiconducting material of semiconductor wafers or samples.

2. Description of Related Art

The determination of electrical properties of a. dielectric layer of a semiconductor wafer or sample is a critical factor in the production of such wafers or samples. In current standard practice, measurements of these electrical properties have been accomplished by first fabricating one or more metal or doped polysilcon contacts on the top surface of the dielectric layer. These contacts become part of the structure that is used to make appropriate measurements. In other words, these contacts become permanent features on the semiconductor wafer or sample, or dielectric layer thereof. Fabrication of metal or polysilicon contacts is time consuming and costly. It typically involves depositing and forming metal or polysilicon contacts on the surface of the semiconductor wafer or sample in a manner known in the art.

An alternative to these fabricated contacts is described in an article entitled “Vacuum Operated Mercury Probe For CV Plotting and Profiling” by Albert Lederman, Solid State Technology, August 1981, pp. 123-126. This article discloses utilizing mercury contacts to replace aluminum or polysilicon contacts. More specifically, the Lederman article discloses a vacuum operated mercury probe for performing measurements of metal oxide semiconductor wafers or samples, homogeneous semiconductor wafers or samples, non-homogeneous semiconductor wafers or samples, and semiconductor wafers or samples on insulating substrates. Problems may arise using the Lederman mercury probe in that mercury may react chemically with the materials on the wafer or sample under study. The use of mercury can also pose a significant safety problem under some conditions. Thus, a mercury probe has limited application.

An alternative to fabrication of metal or polysilicon contacts or the use of mercury contacts for destructive testing of the dielectric layer of a semiconductor wafer or sample is the use of a conductive contact, for example, a contact having an elastically deformable and electrically conductive tip that deforms within its elastic limits when it touches the top surface of the dielectric layer but does not damage the top surface of the dielectric layer. Heretofore, such conductive contact was made entirely of tantalum, a conductive elastomer or a conductive polymer. Alternatively, the conductive contact can be formed of any suitable and/or desirable electrically conductive base material having a layer of tantalum, conductive elastomer or conductive polymer thereon which comes into contact with the top surface of the dielectric layer.

Attempts to use such conductive contacts for destructive testing of dielectric layers of semiconductor wafers or samples, however, have not been found satisfactory because they adversely affect the taking of measurement(s) and the repeatability of taking such measurement(s).

### SUMMARY OF THE INVENTION

A method of testing a dielectric layer of a semiconductor wafer or sample includes (a) providing a semiconductor wafer or sample having a dielectric layer overlaying a substrate of semiconducting material; (b) causing a contact to touch a top surface of the dielectric layer, wherein at least a portion of the contact touching the dielectric layer is formed of iridium; (c) applying to the contact touching the top surface of the dielectric layer a controlled electrical stimulus that causes the dielectric layer to breakdown; (d) determining either a value of the controlled electrical stimulus where the breakdown occurs or a time for the breakdown to occur in response to the application of the controlled electrical stimulus; and (e) determining from the value or time determined in step (d) whether one or more properties of the dielectric layer are within acceptable tolerance.

For determining the value in step (d), the controlled electrical stimulus can be either: an increasing value DC voltage or an increasing value DC current. The increasing value DC voltage or increasing value DC current can be step increased.

For the increasing value DC voltage, the current through the dielectric layer can increase upon breakdown of the dielectric layer. For the increasing value DC current, the voltage across the dielectric layer can decrease upon breakdown of the dielectric layer.

For determining the time in step (d), the controlled electrical stimulus can be either a fixed value DC voltage or a fixed value DC current.

The contact can have the form of an elongated probe. The contact can be formed entirely of iridium.

### BRIEF DESCRIPTION OF THE DRAWINGS

FIG. 1 is a combined block diagram and cross-sectional view of an embodiment of a semiconductor wafer or sample test system;

FIG. 2 is a plot of current versus voltage showing where intrinsic breakdown of a dielectric layer overlaying the semiconducting substrate of the semiconductor wafer or sample occurs in response to the application of an increasing voltage to the dielectric layer in contrast to a defect-related breakdown of the dielectric layer;

FIG. 3 is a plot of voltage versus current showing where intrinsic breakdown of a dielectric layer overlaying the semiconducting material of the semiconductor wafer or sample occurs in response to the application of an increasing current to the dielectric layer in contrast to a defect-related breakdown of the dielectric layer; and

FIG. 4 is a plot of voltage versus time for intrinsic breakdown of a dielectric layer overlaying the semiconducting substrate of the semiconductor wafer or sample in response to an applied voltage or current over time and a defect-related breakdown of the dielectric layer.

### DETAILED DESCRIPTION OF THE INVENTION

The present invention will be described with reference to the accompanying figures.

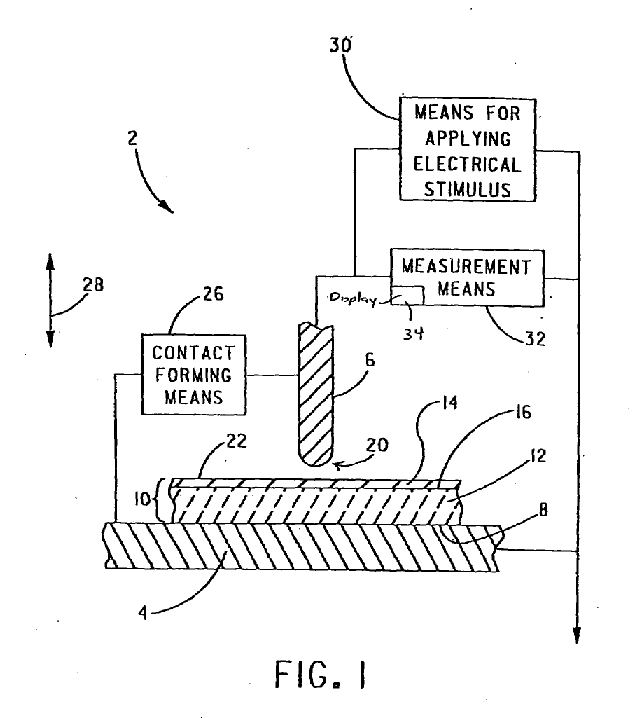

With reference to FIG. 1, a semiconductor wafer or sample test system 2 includes an electrically conductive vacuum chuck 4 and a contact 6. The illustration of contact 6 in the form of an elongated probe is not to be construed as limiting the invention since it is envisioned that contact 6 can have any shape or form suitable for testing a semiconductor wafer or sample under test.

Chuck 4 is configured to support a backside 8 of a semiconductor wafer or sample 10 under test which includes a substrate 12 formed of semiconducting material which is held in contact with chuck 4 by means of a vacuum (not shown). As will be appreciated by one skilled in the art of semiconductor wafer or sample processing and testing, substrate 12 of semiconductor wafer or sample 10 can be formed of any suitable semiconducting material known in the art, such as, without limitation, silicon (Si), germanium (Ge), gallium arsenide (GaAs), and the like. Semiconductor wafer or sample 10 includes a dielectric or oxide layer or film 14, e.g., SiO₂, overlaying a topside 16 of substrate 12. In contrast to the thickness of dielectric layers formed as late as ten years ago, dielectric or oxide layers or films formed today are ultra-thin having a thickness no more than 50 nanometers and, desirably, no more than 35 nanometers.

Contact 6 can have at least a partially spherical and conductive surface 20 for contacting a topside 22 of dielectric layer 14. While a partially spherical conductive surface 20 is desired, it is envisioned that surfaces having other shapes (not shown) suitable for testing a semiconductor wafer or sample 10 can be utilized. Accordingly, the illustration in FIG. 1 of conductive surface 20 being partially spherical is not to be construed as limiting the invention.

At least conductive surface 20 of contact 6 is formed of the element iridium. Alternatively, all of contact 6 may be formed of iridium. However, this is not to be construed as limiting the invention since it is envisioned that only conductive surface 20 is formed of iridium and the body of contact 6 is formed of any other suitable and/or desirable conductive material. For purposes of describing the present embodiment, it will be assumed hereinafter that contact 6 is formed entirely of iridium.

A contact forming means 26, of a type well-known in the art, controls the vertical movement of chuck 4 and/or contact 6, in one or both of the directions shown by two-headed arrow 28, to move contact 6 and semiconductor wafer or sample 10 into contact whereupon surface 20 of contact 6 presses into contact with topside 22 of dielectric layer 14.

A means for applying electrical stimulus 30 can be operative for applying a suitable electrical stimulus to contact 6 and semiconductor wafer or sample 10 when it is received on chuck 4 and surface 20 of contact 6 is in contact with topside 22 of dielectric layer 14.

A measurement means 32 can be operative for measuring the response of semiconductor wafer or sample 10 and, more particularly, dielectric layer 14, to the test stimulus applied by the means for applying electrical stimulus 30 and for processing the measured response in any suitable and desirable manner. A display 34 or any other suitable output means can also be operative for enabling measurement means 32 to output in a human perceivable form the results of any processing performed by measurement means 32 on the measured response of semiconductor wafer or sample 10. Chuck 4 can be connected to a reference ground. However, this is not to be construed as limiting the invention since, alternatively, chuck 4 can be connected to an AC or DC reference bias.

Dielectric layer 14 can be tested in one of two manners. First, an increasing value electrical stimulus can be applied across dielectric layer 14 until breakdown is observed. Alternatively, a high level electrical stimulus can be applied across dielectric layer 14 that initially does not cause dielectric layer 14 to breakdown but, over time, such high level electrical stimulus causes breakdown of dielectric layer 14. Embodiments of these will now be described.

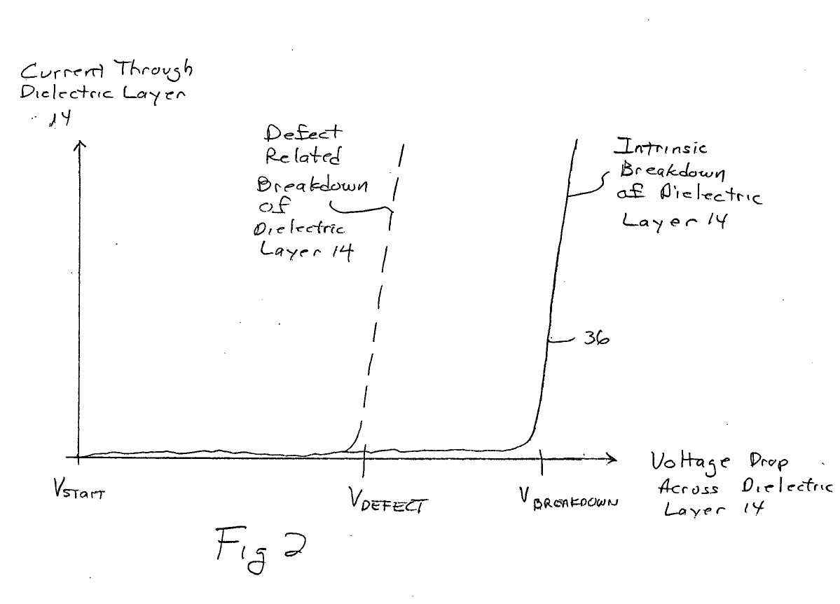

With reference to FIG. 2 and with continuing reference to FIG. 1, means for applying electrical stimulus 30 can apply an IV-type electrical stimulus to contact 6 and semiconductor wafer or sample 10 when it is received on chuck 4 and conductive surface 20 of contact 6 is in contact with topside 22 of dielectric layer 14. An exemplary IV-type electrical stimulus includes sweeping a DC voltage from a starting voltage (V_{START}) to a breakdown voltage (V_{BREAKDOWN}) and measuring the DC voltage and the corresponding current (I) that flows in contact 6 during the sweep. More specifically, measurement means 32 measures a plurality of discrete DC voltage-current data points during the sweep of the DC voltage from V_{START} to V_{BREAKDOWN} and stores these data points in a memory (not shown) of measurement means 32. An exemplary IV curve 36 derived or defined from the DC voltage-current data points acquired by measurement means 32 during the application of an exemplary IV-type electrical stimulus to semiconductor wafer or sample 10 is shown in FIG. 2. IV curve 36 is provided solely for the purpose of describing the present embodiment. Thus, the illustration of IV curve 36, including its shape and the location of V_{START}, V_{BREAKDOWN}, and the like are not to be construed as limiting the invention.

The DC voltage from which IV curve 36 is derived, can be swept in a continuously increasing manner from V_{START} to V_{BREAKDOWN}, can be step increased from V_{START} to V_{BREAKDOWN}, or can be increased in any other suitable and/or desirable manner from V_{START} to V_{BREAKDOWN} that enables IV curve 36 to be derived.

Desirably, the DC voltage applied to dielectric layer 14 is ramped or increased rapidly, whereupon the electric field in dielectric layer 14, not a duration of said electric field, is the factor driving breakdown. As can be seen in FIG. 2, the value of V_{BREAKDOWN} is the voltage where dielectric layer 14 experiences breakdown and the current thereacross transitions from the low level tunneling current shown to the left of V_{BREAKDOWN} to the high level direct tunneling current shown at and to the right of V_{BREAKDOWN}. This is due to a stress-related reduction in the insulating properties of dielectric layer 14 due to the application of excessive electrical stress thereto.

The voltage corresponding to V_{BREAKDOWN} in semiconductor wafer or sample 10 can be compared to like breakdown voltages of reference semiconductor wafers or samples (not shown) to determine whether dielectric layer 14 of semiconductor wafer or sample 10 is within an acceptable tolerance.

If, for example, dielectric layer 14 of semiconductor wafer or sample 10 experiences breakdown at a voltage which is less than V_{BREAKDOWN} and outside the established acceptable tolerance therefor, e.g., V_{DEFECT} in FIG. 2, it can be deduced that dielectric layer 14 is defective, whereupon it can be further deduced that semiconductor wafers or samples from the same lot as semiconductor wafer or sample 10 and having dielectric layers formed under the same conditions as dielectric layer 14 on semiconductor wafer or sample 10 should not be used for producing finished integrated circuits.

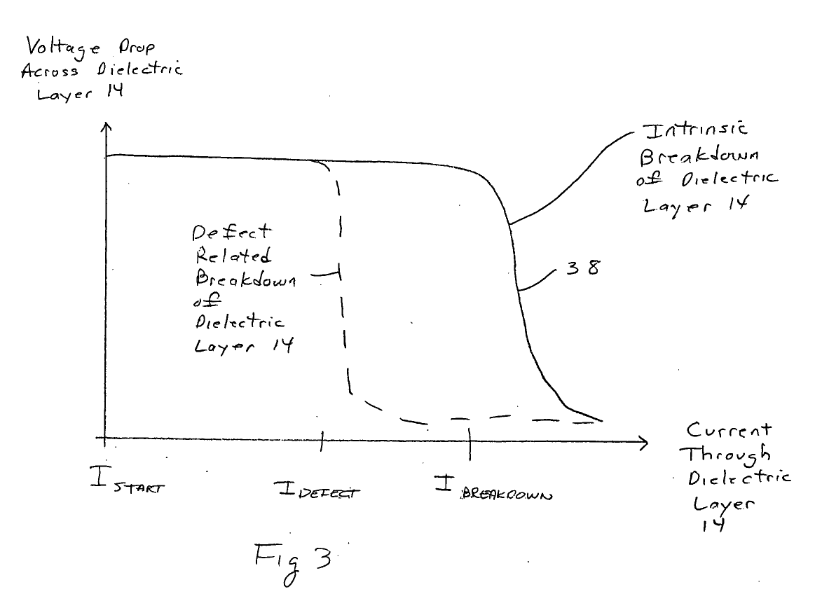

With reference to FIG. 3 and with continuing reference to FIGS. 1 and 2, alternatively, means for applying electrical stimulus 30 can apply an increasing value DC current (from I_{START} to I_{BREAKDOWN}) to dielectric layer 14, via conductive surface 20 of contact 6 in contact with top surface 22 of dielectric layer 14, and measurement means 32 can measure the voltage drop across dielectric layer 14 in response to the application of said increasing value DC current.

When breakdown of dielectric layer 14 occurs, the voltage drop across dielectric layer 14 decreases. This is due to a stress-related reduction in the insulating properties of dielectric layer 14 due to the application of excessive electrical stress thereto. A plot 38 showing the decrease in voltage across dielectric layer 14 in response to the current through dielectric layer 14 reaching I_{BREAKDOWN} is shown in FIG. 3.

Measurement means 32 can compare the value of I_{BREAKDOWN} determined for semiconductor wafer or sample 10 to one or more values of I_{BREAKDOWN} for reference semiconductor wafers or samples to determine if dielectric layer 14 of semiconductor wafer or sample 10 is within acceptable tolerance.

If breakdown of dielectric layer 14 occurs at a current I_{DEFECT} which is less than I_{BREAKDOWN} and outside the established acceptable tolerance therefor, it can be deduced that dielectric layer 14 of semiconductor wafer or sample 10 is defective, whereupon it can be further deduced that semiconductor wafers or samples from the same lot as semiconductor wafer or sample 10 and having dielectric layers formed under the same conditions as dielectric layer 14 on semiconductor wafer or sample 10 should not be used for producing finished integrated circuits.

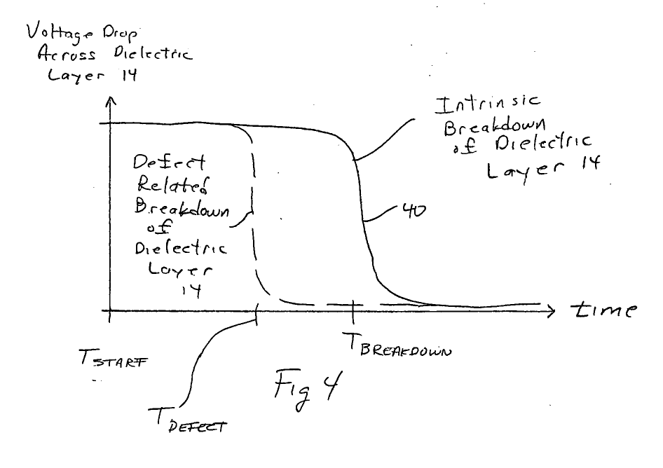

With reference to FIG. 4 and with continuing reference to FIGS. 1-3, alternatively, means for applying electrical stimulus 30 can apply across dielectric layer 14, via contact 6 having conductive surface 20 in contact with top surface 22 of dielectric layer 14, a voltage that causes a predetermined current to flow through dielectric layer 14. The values of voltage and current are selected whereupon dielectric layer 14 does not initially exhibit breakdown. However, after a sufficient interval of time between T_{START} (where the voltage is initially applied across dielectric layer 14) and T_{BREAKDOWN} (where dielectric layer 14 experiences breakdown), measurement means 32 measures a drop in voltage across dielectric layer 14, which drop corresponds to breakdown of dielectric layer 14 due to stress-related reduction of the insulating properties thereof caused by the prolonged application of excessive electrical stress thereto. A plot 40 showing the decrease in voltage across dielectric layer 14 in response to the prolonged application of electrical stress thereto is shown in FIG. 4.

The time interval between T_{START} and T_{BREAKDOWN} can be compared to like time intervals for reference semiconductor wafers or samples to determine if the time interval determined for semiconductor wafer 10 under test is within acceptable tolerance.

If breakdown of dielectric layer 14 occurs at a time T_{DEFECT} which is less than T_{BREAKDOWN} after T_{START} and outside the established acceptable time interval tolerance for breakdown, it can be deduced that dielectric layer 14 of semiconductor wafer or sample 10 is defective, whereupon it can be further deduced that semiconductor wafers or samples from the same lot as semiconductor wafer or sample 10 and having dielectric layers formed under the same conditions as dielectric layer 14 on semiconductor wafer or sample 10 should not be used for producing finished integrated circuits.

Also or alternatively, means for applying electrical stimulus 30 can apply a predetermined current to dielectric layer 14 at time T_{START}. Measurement means 32 can measure the voltage drop across dielectric layer 14 in response to this current and can determine breakdown of dielectric layer 14 upon observing a sudden drop in the voltage across dielectric layer 14 at time T_{BREAKDOWN}. The time interval between T_{START} and T_{BREAKDOWN} in response to the applied current can be compared to like time intervals for like current values applied to reference semiconductor wafers or samples to determine if dielectric layer 14 of semiconductor wafer or sample 10 is within acceptable tolerance.

If breakdown of dielectric layer 14 is observed at a time T_{DEFECT}, whereupon the time interval between T_{START} and T_{DEFECT} is outside of the established acceptable tolerance, it can be deduced that dielectric layer 14 is defective, whereupon it can be further deduced that semiconductor wafers or samples from the same lot as semiconductor wafer or sample 10 and having dielectric layers formed under the same conditions as dielectric layer 14 on semiconductor wafer or sample 10 should not be used for producing finished integrated circuits.

The use of contact 6 having at least conductive surface 20 thereof made of iridium improves the taking of measurements in the manner described above. Specifically, the present inventor has discovered that when made from iridium, conductive surface 20 of probe 6 does not affect the taking of measurement(s) or the repeatability of taking such measurement(s) in the manner of contacts having conductive surfaces 20 made from other elements or materials, such as, without limitation, tantalum, a conductive elastomer, or a conductive polymer. To this end, prior to the present invention, the benefits of using a probe 6 having at least a conductive surface 20 thereof made from iridium for destructive testing the dielectric layers of multiple semiconductor wafers or samples, e.g., in a production environment, was not known. Accordingly, measurements of the type discussed above were made by way of a metal or doped polysilicon contact fabricated on top surface 22 of dielectric layer 14, or by way of a liquid mercury contact deposited atop surface 22 of dielectric layer 14. However, as discussed above, the fabrication of metal or polysilicon contact is time consuming and costly, and the use of mercury poses significant safety problems in its use. Accordingly, prior to the present invention, no effective means existed for performing real-time destructive measurements of dielectric layers 14 of multiple semiconductor wafers or samples utilizing the contact arrangement of the present embodiment on dielectric layers 14 having a thickness of no greater than 50 nanometers and, desirably, no greater than 35 nanometers.

The invention has been described with reference to an example embodiment. Obvious modifications and alterations will occur to others upon reading and understanding the preceding detailed description. It is intended that the invention be construed as including all such modifications and alterations insofar as they come within the scope of the appended claims or the equivalents thereof.

The invention claimed is:

1. A method of testing a dielectric layer of a semiconductor wafer or sample, the method comprising:
(a) providing a semiconductor wafer or sample having a dielectric layer overlaying a substrate of semiconducting material;
(b) causing a contact to touch a top surface of a dielectric layer, wherein at least a portion of the contact touching the dielectric layer is formed of iridium;
(c) applying to the contact touching the top surface of the dielectric layer a controlled electrical stimulus that causes breakdown of the dielectric layer;
(d) determining either a value of the controlled electrical stimulus where the breakdown occurs or a time for the breakdown to occur in response to the application of the controlled electrical stimulus; and
(e) determining from the value or time determined in step (d) whether the dielectric layer is within acceptable tolerance.

2. The method of claim 1, wherein, for determining the value in step (d), the controlled electrical stimulus is either:
an increasing value DC voltage; or
an increasing value DC current.

3. The method of claim 2, wherein the increasing value DC voltage or the increasing value DC current is step increased.

4. The method of claim 2, wherein:
for the increasing value DC voltage, the current through the dielectric layer increases upon breakdown of the dielectric layer; and
for the increasing value DC current, the voltage across the dielectric layer decreases upon breakdown of the dielectric layer.

5. The method of claim 1, wherein, for determining the time in step (d), the controlled electrical stimulus is either a fixed value DC voltage or a fixed value DC current.

6. The method of claim 1, wherein the contact has the form of an elongated probe.

7. The method of claim 1, wherein the contact is formed entirely of iridium.
